(19) United States
(12) Patent Application Publication
(10) Pub. No.: US 2025/0267976 A1
(43) Pub. Date: Aug. 21, 2025

(54) SEMICONDUCTOR MATERIAL INCLUDING TRANSITION METAL DICHALCOGENIDE THIN FILM AND METHOD FOR PRODUCING SAME, AND LIGHT-RECEIVING ELEMENT INCLUDING THE SEMICONDUCTOR MATERIAL

(71) Applicants: TANAKA KIKINZOKU KOGYO K.K., Tokyo (JP); University Industry Foundation, Yonsei University, Seoul (KR)

(72) Inventors: Tatsuya NAKAZAWA, Isehara-shi (JP); Hyung Jun KIM, Seoul (KR); Dong Hyun KIM, Seoul (KR)

(73) Assignees: TANAKA KIKINZOKU KOGYO K.K., Tokyo (JP); University Industry Foundation, Yonsei University, Seoul (KR)

(21) Appl. No.: 18/273,525

(22) PCT Filed: Jan. 13, 2022
(86) PCT No.: PCT/JP2022/000923

§ 371 Date: Nov. 30, 2023

(30) Foreign Application Priority Data
Jan. 26, 2021 (JP) 2021-010227

(51) Int. Cl. H10F 77/12; C23C 28/04; H10F 71/00

(52) U.S. Cl. CPC H10F 77/127; C23C 28/04; H10F 71/00

(57) ABSTRACT

The present invention relates to a semiconductor material including a thin film formed on a base material, the thin film including a transition metal dichalcogenide represented by MX₂, wherein M is a transition metal and X is a chalcogen atom except oxygen. In the present invention, the thin film is modified with metal nanoparticles including metallic N, whereby defect portions on the surface of the transition metal dichalcogenide thin film are modified to thereby improve the semiconductor characteristics of the thin film. These metal nanoparticles are preferably the nanoparticles of a precious metal. The transition metal M in the transition metal dichalcogenide thin film on the base material is preferably a sulfide, selenide or telluride of Pt or Pd. In the step of modifying with the metal nanoparticles, an atomic layer deposition method (ALD) is particularly preferably applied.

### BACKGROUND OF THE INVENTION

### Field of the Invention

The present invention relates to a semiconductor material having a thin) film including a transition metal dichalcogenide. In detail, the present invention relates to a semiconductor material including a transition metal dichalcogenide thin film whose surface defect has been repaired to improve the response characteristic, and a production method thereof.

### Description of the Related Art

In recent years, as semiconductor materials for semiconductor devices, including light-receiving devices such as a light-receiving element and a solar cell, and field-effect transistors (FET), transition metal dichalcogenide (TMDC) has been attracting attention. A transition metal dichalcogenide refers to a compound (MX₂) of a metal (M) of a Group 3 element to Group 11 element, which belongs to transition metals, and a chalcogen element (X) except oxygen. Transition metal dichalcogenides exhibit peculiar electric characteristics or optical semiconductor characteristics according to the kind of the central metal M, and are therefore used in a variety of applications described above (for example, Patent Document 1).

An example of a particularly expectant use to which the transition metal dichalcogenides is applied is an element for converting light to electricity for light-receiving elements such as sensors. As an example thereof, light-receiving elements that are applied to light detection and ranging (LIDAR) will be described. LIDAR is a sensing technique where laser light is used, and is a system in which a subject is irradiated with laser light, followed by sensing a reflected light with a light-receiving element to detect the distance or angle to the subject. LIDAR is advantageously capable of highly accurately detecting the distance or angle to a subject, compared with detecting systems where a camera or a millimeter-wave radar is used. In addition, LIDAR has been thus far a technique utilized as a remote sensing system in automobile self-driving, drones, ships and others. In addition, LIDAR also has been applied recently to face recognition techniques or augmented reality in smartphones, tablets or the like.

Examples of semiconductor materials that have been thus far being studied to be applied to light-receiving elements for LIDAR include HgCdTe alloys (Hg₁₋ₓCdₓTe alloys: MCT alloys) and InGaAs alloys (In₁₋ₓGaₓAs alloys) (for example, Patent Document 2 and Patent Document 3). In these semiconductor alloys, it is possible to adjust the band gaps by setting an appropriate composition (x) and to detect a wide range of infrared rays of 1 to 30 μm. Light-receiving elements (photoconductive elements) including these alloys have already been commercially available.

However, upon application of HgCdTe alloys or InGaAs alloys to light-receiving elements for LIDAR, several problems have been pointed out. As these problems, a problem in terms of performance can be firstly mentioned. HgCdTe alloys have a small SN ratio at room temperature, and thus elements need to be cooled to be operated with no generation of noise. The cooling temperature is also said to be 80 K or lower. Therefore, addition of a cooling mechanism to systems that are used at room temperature is necessary, which is not preferable for drones, smartphones and others for which size reduction is essential. Furthermore, HgCdTe alloys are also difficult to use in automobile equipment for which operation at room temperature is premised. In addition, it have also been pointed out that InGaAs alloys have poor responsiveness at room temperature and, additionally, other problems of InGaAs alloys are that operating voltages are high and that the structure is unstable.

In addition, devices including HgCdTe alloys and InGaAs alloys also have a problem with cost. The use of molecular beam epitaxy (MBE) has become essential to produce these alloys in desired compositions. MBE is a thin film formation process that is performed in an ultrahigh vacuum and has a low production efficiency since the time necessary to form thin films with a desired thickness is long. In addition, in the case of producing HgCdTe alloys and InGaAs alloys by MBE, the material for a substrate are limited to CdZnTe, GaAs and the like, which are expensive. Due to these production efficiency and cost of the substrate, the cost of light-receiving elements to which HgCdTe alloys and InGaAs alloys are applied is high. This problem in terms of cost acts as a barrier to the spread of LIDAR.

Therefore, what is expected as light-receiving elements for LIDAR or the like is transition metal dichalcogenides. Transition metal dichalcogenides are two-dimensional materials having a layered structure and are capable of exhibiting photoresponsivity in which the band gap changes depending on the number of layers therein. Therefore, transition metal dichalcogenides have been reported to have a large SN ratio in the room temperature range and will solve the problem in terms of performance during use in the room temperature range.

In addition, transition metal dichalcogenides can be produced by a variety of thin film formation processes. Particularly, transition metal dichalcogenides can be produced by a chemical deposition method such as a chemical vapor deposition method (CVD method) or an atomic layer deposition method (ALD method). The chemical deposition method is known as a high-yield thin film formation process. In addition, in manufacturing transition metal dichalcogenides by the chemical deposition method, there is a wide choice of the material for the substrate, and thin films can be formed on Si wafers or glass substrates (SiO₂). Therefore, semiconductor materials including transition metal dichalcogenides are deemed to be superior in terms of cost as well.

### PRIOR ART DOCUMENT

### Patent Documents

### Patent Document 1

Japanese Translation of PCT International Application Publication No. 2018-525516

### Patent Document 2

Examined Japanese Patent Application Publication No. H6-9240

### Patent Document 3

Japanese Patent Application Laid-Open No. 2007-165359

### SUMMARY OF THE INVENTION

### Technical Problem

As described above, transition metal dichalcogenides have a number of advantages, compared to conventional optical semiconductor materials such as HgCdTe alloys. However, transition metal dichalcogenides are relatively novel materials and are also materials for which there are still a number of unknown aspects in terms of characteristic improvement, development of efficient production processes, and others. For the application to light-receiving elements for LIDAR or the like exemplified above as well, transition metal dichalcogenides are required not only to have a light-receiving sensitivity in predetermined wavelength ranges but also to attain improvement in performance including higher light-receiving sensitivity and response characteristic.

The present invention has been made in consideration of the above-described circumstances, and an objective of the present invention is to provide a semiconductor material including a transition metal dichalcogenide thin film that is capable of improving performance more than ever. In addition, a method for producing such a semiconductor material including a transition metal dichalcogenide thin film and a method for improving the same are disclosed.

### Solution to Problem

In order to solve the above-described problems, the present inventors have conducted intensive studies and paid attention to the presence of a surface defect as a starting point for improvement in performance of transition metal dichalcogenides. Transition metal dichalcogenides are two-dimensional substances in which metal atoms and chalcogen atoms bond to each other through ionic bonds and/or covalent bonds and the atoms are regularly disposed. In ideal transition metal dichalcogenides, there are no collapse of the arrangement regularity of individual constituent atoms. However, in actual cases, defects are present on the surfaces of transition metal dichalcogenide thin films, regardless of production processes. Such surface defect is a factor of disturbing the regularity of atomic arrangement, including a dislocation and a lattice defect as well as a dangling bond (an unbound site) or an edge site near a lattice defect. In addition, such a surface defect traps a carrier and acts as a starting point of a leak path by recombination and thus can act as a cause for performing semiconductor characteristics that transition metal dichalcogenides are supposed to exhibit.

Therefore, it is deemed that the generation of a surface defect in the production process needs to be suppressed in order for the improvement in performance of semiconductor materials including transition metal dichalcogenides. However, it is not necessarily easy to produce transition metal dichalcogenides in which regularity is completely maintained with no defects, and it is thus difficult to say that an approach only from production methods is realistic means. Then, the present inventors have conceived that, on the surface of an arbitrarily-produced transition metal dichalcogenide thin film, defect portions are preferentially modified with metal nanoparticles to suppress carriers from being trapped by defects.

Specifically, the present invention is a semiconductor material including: a base material, and a thin film formed on the base material and including a transition metal dichalcogenide represented by MX₂, wherein M is a transition metal and X is a chalcogenide, in which the semiconductor material includes metal nanoparticles including metallic N and modifying a surface of the thin film.

As described above, the semiconductor material containing a transition metal dichalcogenide of the present invention includes the base material and the thin film including a transition metal dichalcogenide, and also the metal nanoparticles on the thin film, as a basic configuration. Hereinafter, the configuration and production method of the semiconductor material of the present invention and a light-receiving element to which the semiconductor material of the present invention is applied will be described.

### (A) Configuration of Semiconductor Material of Present Invention

### (A-1) Base Material

The base material is a member for supporting the thin film including the transition metal dichalcogenide. The material of the base material may be any material as long as it is possible to support the thin film including the transition metal dichalcogenide. Examples thereof include materials such as glass, quartz, silicon, ceramic and metal. The shape and dimensions of the base material are not particularly limited.

### (A-2) Transition Metal Dichalcogenide Thin Film

As described above, the transition metal dichalcogenide refers to a compound (MX₂) of a metal (M) of a Group 4 element to Group 11 element, which belongs to transition metals, and a chalcogen element (X) except oxygen. Specific examples of the transition metal in the semiconductor material of the present invention include tungsten (W), molybdenum (Mo), platinum (Pt), ruthenium (Ru), rhodium (Rh), palladium (Pd), osnium (Os), iridium (Ir), hafnium (Hf), and zirconium (Zr). Examples of the chalcogen element include sulfur(S), selenium (Se) and tellurium (Te).

A preferable transition metal dichalcogenide in the present invention is a chalcogenide in which the transition metal is a platinum group metal (Pt or Pd). Such a transition metal dichalcogenide is specifically PtSe₂, PtS₂, PtTe₂, PdSe₂, PdS₂ or PdTe₂. These transition metal dichalcogenides have a band gap smaller by approximately 1 eV than those of transition metal dichalcogenides containing Mo or W as the central metal, and have a high mobility (carrier mobility), which is a characteristic of transition metal dichalcogenides, and thus these transition metal dichalcogenides are expected to have excellent photoresponsivity.

The transition metal dichalcogenide is a two-dimensional substance in which individual constituent elements strongly bond to each other by ionic bonds and/or covalent bonds, and the thin film of the transition metal dichalcogenide has a structure in which unit layers of the two-dimensional substance are laminated in layers. The unit layers bond to each other with a relatively weak bond (Van der Waals force). The thin film of the transition metal dichalcogenide in the present invention can be composed of a single unit layer or a plurality of the unit layers. Since the band gap as a semiconductor thin film changes depending on the number of the layers, the number of the layers is adjusted in accordance with a device to which the semiconductor material is applied. Therefore, in the present invention, there is no need to limit the thickness of the transition metal dichalcogenide thin film. For example, in the case of application to optical elements for LIDAR, the number of the layers is preferably one or more and four or less and more preferably one or more and two or less. The thickness of the thin film at this time is 0.5 to 5 nm.

### (A-3) Metal Nanoparticles

### (A-3-1) Action and Configuration of Metal Nanoparticles

Modification of the surface of the transition metal dichalcogenide thin film with the metal nanoparticles is a main characteristic of the present invention. Here, modification in the present invention refers to a state where the metal nanoparticles and the transition metal dichalcogenide thin film bond to each other by the adsorption force due to physical adsorption, chemical adsorption or the like, or the bonding force due to metallic bonds, ionic bonds, covalent bonds or the like. When defect portions in the transition metal dichalcogenide thin film are modified with the metal nanoparticles, trapping of carriers by the defects is inhibited. This suppresses the deterioration of response characteristic caused by the recombination of unnecessary carriers.

The metal nanoparticle is a nano-sized particle including metallic N. The carrier trapping-inhibiting mechanism by the metal nanoparticles is based on Schottky junctions formed between the transition metal dichalcogenide and the metal nanoparticles. The formation of the Schottky junctions causes band bending and makes electrons flow into the metal nanoparticles. Since Schottky barriers make it difficult for the electrons that have flowed into the metal nanoparticles to return to the transition metal dichalcogenide thin film, and recombination with carriers is thus suppressed to improve electron lifetime.

Specifically, the particle diameters of these nano-sized metal nanoparticles are preferably 2 nm or more and 50 nm or less. Since the formation of metal nanoparticles having excessively small particle diameters is difficult, the lower limit value is 2 nm. On the other hand, metal nanoparticles larger than 50 nm are not preferable because of the following: Schottky barriers is high and the thickness of a depletion layer is thicker than necessary in that case, which makes the effect of hot electrons injected into a semiconductor layer disappear. The average particle diameter of the metal nanoparticles is more preferably 20 nm or more and 50 nm or less. This is because such an average particle diameter can more effectively form local Schottky barrier junctions between the metal nanoparticles and the transition metal dichalcogenide thin film.

The metallic N of the metal nanoparticles is preferably a metal having a larger work function than the band gap of the transition metal dichalcogenide (MX₂: PtSe₂ etc.) of the thin film. The joining of a metal having a large work function makes the carrier trapping-suppressing effect by the Schottky junctions clearer. An increase in local surface electrolysis by the formation of the Schottky junctions and an accompanying increase in the width and height of the depletion layer increases spatial separation between electrons and carriers excited by light energy, and thus extend electron lifetime. When the transition metal dichalcogenide thin film is modified with the metal nanoparticles having a large work function, the above-described effect can be effectively exhibited to increase photocurrents.

The typical band gaps of the above-exemplified preferable transition metal dichalcogenides are as follows: PtSe₂ (1.20 eV (single layer) to 0.21 eV (two layers)), PtS₂ (2.66 eV (single layer) to 0.25 eV (two layers)), PdSe₂ (2.55 eV (single layer) to 1. 89 eV (two layers)), PtS₂ (1.28 eV (single layer) to 1.03 eV (two layers)). The metallic N in the present invention is preferably a metal having a work function of 3.0 eV or more and more preferably a metal having a work function of 4.0 eV or more.

A specific preferable example of the metallic N is a precious metal. The precious metal is a metal liable to have a large work function. In addition, the precious metal has excellent environment resistance and thus can be stably present even in a state where the specific surface area is large as in nanoparticles. For this reason, precious metal nanoparticles are preferable. Examples of preferable precious metals include Au, Ag, Pt, Pd, Ir and Ru. The work functions of these precious metals are known to be Au: 5.47 eV, Ag: 4.64 eV, Pt: 5.64 eV, Pd: 4.9 eV, Ir: 5.35 eV and Ru: 4.68 eV. Here, metals having a relatively high work function, such as W, Mo and Ni, also have a possibility of being applied as the metallic N depending on applications although they are not precious metals. The work functions of these metals are known to be W: 4.52 eV, Mo: 4.45 eV and Ni: 5.15 eV.

The constituent metallic N of the metal nanoparticles, which modify the surface of the transition metal dichalcogenide thin film, may be the same metallic element as the metal of the transition metal dichalcogenide thin film or may be a different metallic element.

(A-3-2) Surface Morphology of Thin Film by Modification with Metal Nanoparticles

The metal nanoparticles preferentially modify defects on the surface of the transition metal dichalcogenide thin film. Therefore, the semiconductor material of the present invention has a surface morphology on which, microscopically, particulate unevenness is formed. As described below, the defect portions on the thin film surface have a high surface energy, and the fine metal nanoparticles are preferentially bonded to sites with a high surface energy. Therefore, when the metal nanoparticles are supplied onto the thin film surface at an appropriate rate in an appropriate quantity, the defect portions are preferentially modified. However, as clear from the expression “preferentially modify defects”, the surface modification is not limited to a state where only defects are modified with the metal nanoparticles, and the metal nanoparticles may bond to regions other than the defects. In addition, the metal nanoparticles may be in a state where each particle is independently dispersed or may be coupled to each other.

Modification with excess metal nanoparticles makes the thin film conductive to thereby lose characteristics as a semiconductor. For example, it is not preferable to modify the thin film surface with the metal nanoparticles such that the thin film surface is wholly or almost wholly coated. The amount of the modifying metal nanoparticles can be regulated by the ratio (density) of the metal nanoparticles to the surface area of the thin film.

As a specific criterion, when the surface of the thin film including a transition metal dichalcogenide modified with the metal nanoparticles is observed, it is preferable that the percentage of the total of the areas (projected areas on the thin film surface) of the metal nanoparticles on the thin film be 5% or more of the area of the observation field region. This is because, when the percentage of the area is less than 5%, it is difficult to exhibit the effect by modification with the metal nanoparticles. This lower limit value of the percentage of the area is a value in consideration of application to the surface of a transition metal dichalcogenide thin film including only a small number of defects. On the other hand, when the percentage of the area of the metal nanoparticles is excessively high, the thin film is conductive and loses functions as a semiconductor material, as described above. Therefore, the percentage of the area of the metal nanoparticles is preferably set to 20% or less.

As for a specific method for measuring the percentage of the area of the metal nanoparticles, it is preferable to measure the percentage of the area based on the observation field region in a backscattered electron image obtained by observing the surface of the thin film including the transition metal dichalcogenide and modified with the metal nanoparticles using a scanning electron microscope at a magnification of 50000× to 100000×. The reason for this magnification is that the observation of lattice defects and the metal nanoparticles is not possible when the magnification is too low, and also that, when the magnification is too high, the distribution of the lattice defects and the metal nanoparticles in the observation field region is uneven, which leads to a variation in the observation result.

### (A-4) Specific Applications of Semiconductor Material of Present Invention

The semiconductor material of the present invention is applied as an ordinary semiconductor material, and applications thereof are not particularly limited. For example, the semiconductor material can be used as semiconductor materials in a wide range of applications, including elements for converting light to electricity, light-receiving elements, field effect transistors, optical sensors, photodetectors and magneto-optical memory elements. Particularly, the present invention is suitable as an optical semiconductor material that is applied to optical devices and is useful in application to elements for converting light to electricity, and the like. More specifically, the present invention is suitable for a light-receiving element, can be used in the near-infrared region (wavelengths of 0.7 to 3 μm) and exhibits an excellent light-receiving sensitivity, and the present invention is thus suitable for light-receiving elements for the LIDAR.

(B) Method for producing Semiconductor Material of Present Invention

Next, a method for producing a semiconductor material of the present invention will be described. As described hereinabove, the present invention is characterized in that the surface of the thin film including the transition metal dichalcogenide is modified with the metal nanoparticles. The step of modifying with the metal nanoparticles is essential, but there are no limitations on the step of forming a transition metal dichalcogenide thin film and the step(s) after modification with metal nanoparticle, which are the steps before and after the modifying step. Therefore, the method for producing a semiconductor material of the present invention is a method for producing a semiconductor material including the step of forming a thin film including a transition metal dichalcogenide MX₂ on a base material (film formation step) and the step of modifying the surface of the thin film with metal nanoparticles including metallic N (modification step), in which an atomic layer deposition method is used for the step of modifying with the metal nanoparticles. Hereinafter, each step will be described.

### (B-1) Step of Forming Transition Metal Dichalcogenide Thin Film

A method for forming a transition metal dichalcogenide thin film on the base material is not particularly limited, and a conventional method for producing a transition metal dichalcogenide is applied. Examples of the method for producing a transition metal dichalcogenide include a metal film reaction method in which a transition metal thin film formed on a substrate is thermally treated in a chalcogen element atmosphere (sulfur gas, selenium gas or the like) to produce a chalcogenide, and also a sputtering method (reactive sputtering method) and thin film formation processes, including a physical deposition method such as a vacuum deposition method and a chemical deposition method such as a chemical vapor deposition method (CVD method) and an atomic layer deposition method (ALD method). In the present invention, the latter physical deposition method or chemical deposition method is preferably applied. A particularly preferable film formation method is the chemical deposition method. This is because the chemical deposition method makes it possible to efficiently obtain a transition metal dichalcogenide thin film having a uniform target composition (MX₂).

(B-2) Step of Modifying with Metal Nanoparticles

Defects on the surface of the transition metal dichalcogenide thin film formed above are modified with metal nanoparticles. In this modification step with metal nanoparticles, an atomic layer deposition method (ALD method) is used. The atomic layer deposition method refers to a thin film formation process in which a certain cycle is repeated, and the cycle includes the adsorption step of bringing a raw material gas containing a metal complex as a precursor for modification into contact with the surface of a substance to be treated to thereby adsorb the precursor to the surface of the substance to be treated; the first exhaustion step of exhausting a surplus of the raw material gas; the reaction step of reacting the precursor adsorbed to the surface of the substance to be treated and a reaction gas on the surface to form metal nanoparticles; and the second exhaustion step of exhausting a surplus of the reaction gas.

The atomic layer deposition method is a film formation method which enables film formation in the unit of a single atom layer and therefore highly accurate control of the film thickness. The present inventors have considered that the application of the atomic layer deposition method is essential for the modification with the metal nanoparticles, and the reason for this is that attention was paid to the above-described characteristics of this process, and also that attention was paid to a relationship between the surface state of the transition metal dichalcogenide thin film including defects and the behaviors of precursor molecules (metal complex molecules) in an unreacted state. In the transition metal dichalcogenide thin film, defect portions, which disturb the regularity, have a high surface energy. In addition, the unreacted precursor molecules that are introduced into a reactor and diffuse on the base material have the property of being selectively adsorbed to portions with a high surface energy. An interaction between such defect portions and the precursor molecules effectively acts on the preferential modification of the defects in the transition metal dichalcogenide thin film, which is intended by the present invention.

In contrast, a chemical vapor deposition method (CVD method) belongs to a chemical deposition method, similar to the atomic layer deposition method, and forms films using the same kind of precursor. The CVD method is a method for forming a film by depositing a metal precipitated by heat, a reaction gas or the like on a base material and is poor in terms of the above-described selective modification with the metal nanoparticles. A physical deposition method, such as sputtering, is a method in which metal particles scattered by imparting momentum or the like are deposited on a base material, and thus the selective modification with the metal nanoparticles in the present invention is difficult.

The modification step with metal nanoparticles of the present invention is basically, according to an ordinary atomic layer deposition method, and includes repeating a deposition cycle, and one deposition cycle includes the supply and exhaustion of the above-described precursor gas and the supply and exhaustion of the reaction gas. As the precursor of the metal nanoparticles, a compound (complex) essentially containing metallic N for forming the metal nanoparticles is used, and it is possible to use metal complexes that can be normally used in the chemical deposition method. Regarding platinum, an organic platinum compound such as dimethyl(N,N-dimethyl-3-butane-1-amine-N) platinum (DDAP), 1,5-hexadienedimethylplatinum (HDMP), (trimethyl)methylcyclopentadienylplatinum (MeCpPtMe₃) or bis(acetylacetonato)platinum (Pt(acac)₂) is used, for example. Regarding palladium, an organic palladium compound such as bis(hexafluoroacetylacetonato) (Pd(hfac)₂), cyclopentadienylallyl palladium (CpPd(allyl)) or bis(methylallyl) palladium (Pd(Meallyl)₂) is used. Regarding ruthenium, an organic ruthenium compound such as dicarbonyl-bis(5-methyl-2,4-hexanedionato) ruthenium, hexacarbonyl [methyl-(1-methylpropyl)-butene-aminato]ziruthenium or dodecacarbonyltriruthenium (DCR) is used. Regarding gold, an organogold compound such as trimethylphosphinotrimethylgold, regarding iridium, an organic iridium compound such as tris(acetylacetonato)iridium (Ir(acac)₃) or (cyclohexadienyl)methylcyclopentadienyliridium ((MeCp)Ir(CHD)) is used. Regarding silver, an organic silver compound such as triethylphosphine (6,6,7,7,8,8,8-heptafluoro-2,2-dimethyl-3,5-octandionate) silver (I) (Ag(fod)(PEt₃)) or 1-5 cyclooctadienehexafluoroacetylacetonate silver (I) ([(hfac) (1,5-COD) μg]) is used.

In the atomic layer deposition method, the metal complex, which is the precursor, is vaporized and appropriately supplied onto the base material together with a carrier gas. As the carrier gas, an inert gas, such as argon or nitrogen, is normally used. The supply of the precursor gas makes the precursor molecules selectively adsorbed to the surface defects of the transition metal dichalcogenide thin film. After that, a surplus of the precursor gas in the reactor is exhausted.

After the precursor is adsorbed to the surface of the transition metal dichalcogenide thin film, the reaction gas is introduced to form metal nanoparticles at defect portions. The reaction gas is selected depending on the kind or reactivity of the metal complex serving as the precursor, and a reducing gas such as hydrogen, ammonia or hydrazine or an oxidizing gas such as oxygen or ozone is normally used. Also, an inert gas such as nitrogen can be made, with assisted plasma, into plasma to be used as the reaction gas. The assisted plasma may also be used for the reducing gas or the oxidizing gas. After the supply of the reaction gas, a surplus gas is exhausted.

The above-described steps are regarded as one cycle, and the cycle is repeated a plurality of times, whereby the surface of the transition metal dichalcogenide thin film is modified with a predetermined amount of the metal nanoparticles. The treatment temperature in this modification step is 100° C. or higher and 350° C. or lower depending on the precursor to be used, and the treatment temperature is set mainly by the heating of the base material.

The amount (density) of the metal nanoparticles that modify the surface of the transition metal dichalcogenide thin film in the present invention can be adjusted by the amounts of the precursor and the reaction gas supplied and the number of cycles in the above-described atomic layer deposition method. Regarding exemplary conditions, the precursor is transported into a reaction chamber with an inert gas as the carrier gas at 5 sccm or more and 100 sccm or less. The amount of the reaction gas supplied is 100 to 300 sccm. As the reaction gas, a reducing gas such as hydrogen, ammonia or hydrazine or an oxidizing gas such as oxygen or ozone can be used, as described above, and hydrogen or oxygen is preferable. The reaction chamber and the base material are preferably heated at 100° C. or higher and 350° C. or lower.

The number of cycles is set such that the coverage rate with the nanoparticles becomes appropriate. For example, when DDAP is used in modification with platinum nanoparticles, the number of cycles can be five to 100 in a case where hydrogen is used as the reaction gas, and the number of cycles can be 10 to 200 in a case where oxygen is used as the reaction gas.

The semiconductor material of the present invention can be produced through the modification step with the metal nanoparticles described above. As a treatment after the modification step with the metal nanoparticles, a plasma treatment or an acid treatment can be arbitrarily performed. The semiconductor material produced by the above-described steps can be made into a semiconductor element by attaching an electrode thereto as necessary.

### Advantageous Effects of Invention

As described above, the semiconductor material of the present invention has a superior light-receiving sensitivity to conventional transition metal dichalcogenides and is useful as light-receiving elements. Furthermore, the semiconductor material of the present invention and the method for producing the same satisfy all requirements, specifically, a high light-receiving sensitivity, a low production cost and use at room temperature, and the semiconductor material is particularly suitable as light-receiving elements for LIDAR.

### BRIEF DESCRIPTION OF THE DRAWINGS

FIG. 1 is SEM images showing the surface morphologies of semiconductor materials (Pt/PtSe₂) manufactured in First Embodiment and Comparative Example 1;

FIG. 2 is a view showing the IR response characteristics of the semiconductor materials of First Embodiment and Comparative Example 1;

FIG. 3 is a view showing the carrier lifetime characteristics of the semiconductor materials of First Embodiment and Comparative Example 1;

FIG. 4 is a view showing the IR response characteristics of semiconductor materials of Second Embodiment and Comparative Example 2;

FIG. 5 is a view showing the carrier lifetime characteristics of the semiconductor material of Second Embodiment and Comparative Example 2;

FIG. 6 is a SEM image showing the surface morphology of a semiconductor material (Ru/PtSe₂) manufactured in Third Embodiment; and

FIG. 7 is a view showing the IR response characteristic of the semiconductor material of Third Embodiment.

### DETAILED DESCRIPTION OF THE PREFERRED EMBODIMENTS

First Embodiment: Hereinafter, an embodiment of the present invention will be described. In the present embodiment, a thin film of PtSe₂ as a transition metal dichalcogenide was formed on a base material. Then, the surface of the thin film was modified with Pt particles as metal nanoparticles to produce a semiconductor material. Regarding the manufactured semiconductor material, the photoresponsivity to near-infrared rays was evaluated and the surface morphology was studied.

### [Production of Semiconductor Material]

### Formation of Transition Metal Dichalcogenide Thin Film

A SiO₂ glass substrate (dimensions: 20×20, thickness: 1.5 mm) was provided as a base material, and a PtSe₂ thin film was formed on this base material by a CVD method (thermal CVD). First, the substrate was set in a CVD device (hot wall-type horizontal CVD device), and 5 g of a selenium powder was disposed upstream of the substrate. The substrate temperature and the temperature of the selenium powder were each controllable. The inside of a reactor was purged with an argon gas (200 sccm) before film formation.

Then, a platinum complex (dimethyl(N,N-dimethyl-3-butane-1-amine-N) platinum (DDAP)) was used as a raw material for a thin film. The platinum complex was heated to be vaporized, and introduced together with a carrier gas into the reactor. The platinum complex vaporized was decomposed on the substrate, and platinum and selenium were reacted with each other to precipitate PtSe₂, thereby forming a thin film. The conditions for film formation were as described below. The film thickness of the PtSe₂ thin film formed on the base material in this film formation step was 4 nm. This PtSe₂ thin film is a semiconductor material showing an n-type semiconductor tendency.
Heating temperature of raw material: 67° C.
Carrier gas: Argon/10 sccm
Temperature of substrate/heating temperature of selenium powder: 400° C./220° C.
Film formation time: 15 minutes
   Modification Step with Metal Nanoparticles

Next, the surface of the PtSe₂ thin film formed above was modified with Pt nanoparticles by an atomic layer deposition method. The device used was the same as the CVD device used to form the PtSe₂ thin film. In addition, as a platinum complex that served as a precursor (raw material gas) of Pt nanoparticles, the same DDAP as above was used. The substrate on which the PtSe₂ thin film had been formed was placed in a reactor, and the reactor was purged with argon (80 sccm). Then, the following (1) to (4) was regarded as one cycle.
(1) Introduction of raw material gas
   Heating temperature of raw material: 67° C.
   Carrier gas: Argon/10 sccm
   Introduction time: Four seconds
(2) Exhaustion of raw material gas
   Purged with argon gas (80 sccm)
   Introduction time: Five seconds
(3) Introduction of reaction gas
   Reaction gas: Pure oxygen/150 sccm
   Introduction time: Seven seconds
(4) Exhaustion of reaction gas
   Purged with argon gas (80 sccm)
   Introduction time: Five seconds

In the present embodiment, 10 cycles each consisting of (1) to (4) above were performed to thereby modify the PtSe₂ thin film with the Pt nanoparticles to manufacture a semiconductor material.

Comparative Example 1: As a comparative example with respect to First Embodiment described above, a semiconductor material was manufactured in which modification of surface defects in a PtSe₂ thin film was not performed. In this comparative example, the semiconductor material was produced by forming the PtSe₂ thin film on a substrate in the same manner as in First Embodiment and not performing modification with Pt nanoparticles.

### [Measurement of Average Particle Diameter and Percentage of Area of Metal Nanoparticles]

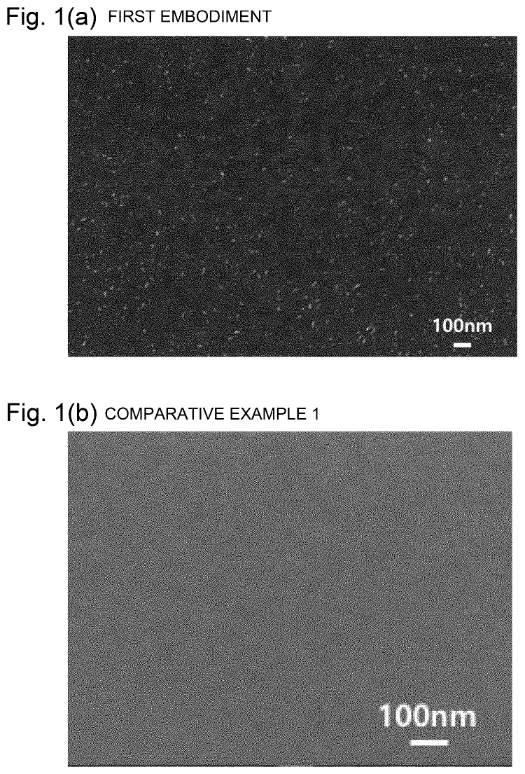

For the Pt nanoparticles on the surface of the semiconductor material of First Embodiment, the average particle diameter and the percentage of the area were measured. FIG. 1 shows an example of a SEM image of the semiconductor material (Pt/PtSe₂) manufactured in First Embodiment. In the measurement of the average particle diameter of the Pt nanoparticles, surface observation was performed with a scanning electron microscope (SEM) at a magnification of 50000×. Then, the particle diameters and the percentage of the area of the Pt nanoparticles were obtained from the SEM image. In the measurement of the particle diameters, 50 particles were arbitrarily extracted from the image, the major axis and minor axis of each were measured, the average value thereof was regarded as the particle diameter, and the average particle diameter of the targeted particles was calculated. Regarding the percentage of the area of the metal nanoparticles, the percentage (%) of the area of the metal nanoparticles in an observation region in the image was calculated. This calculation was performed with image analysis software (name: ImageJ). As for analysis conditions, the image was converted to eight bits and binarized, and the percentage of the area was obtained from the average particle diameter of the nanoparticles, the area of all of the nanoparticles and the area of the measurement region. As a result, the average particle diameter of the Pt nanoparticles was 22.73 nm. The percentage of the area of the Pt nanoparticles was 12.54%.

### [Evaluation of Photoresponsivity of Semiconductor Material]

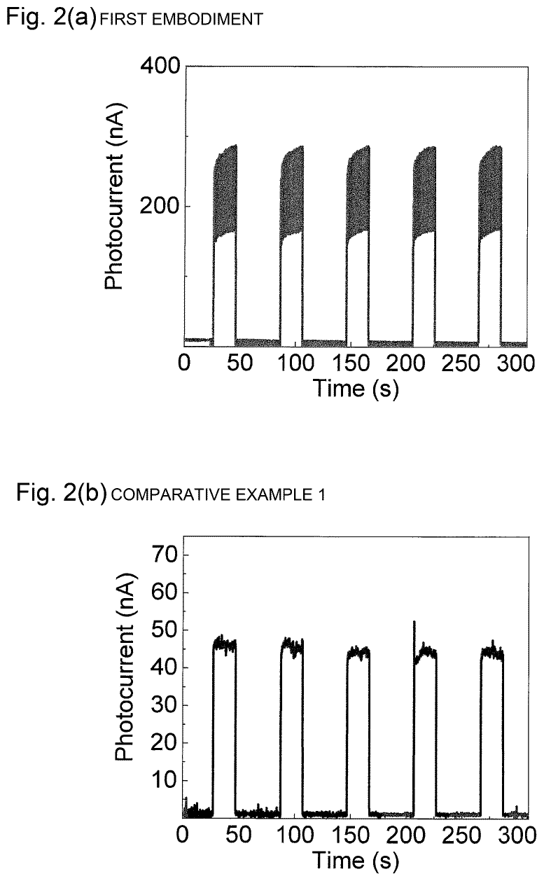

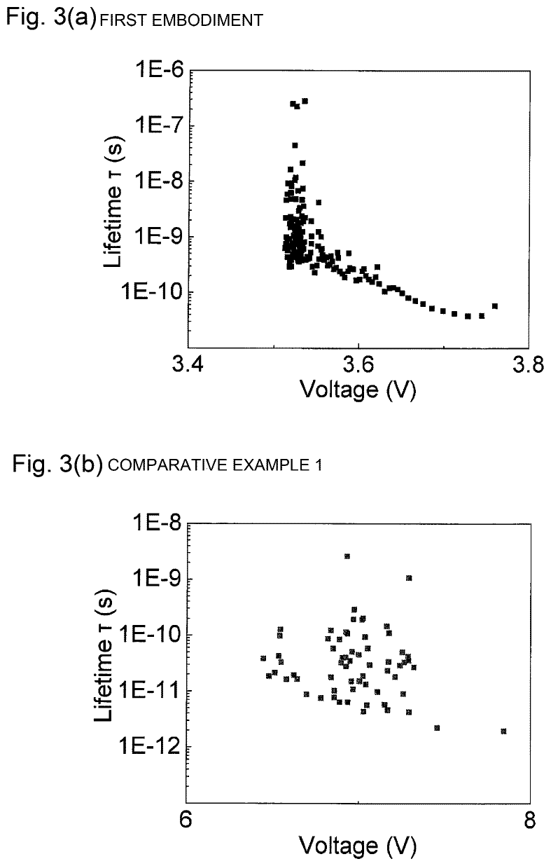

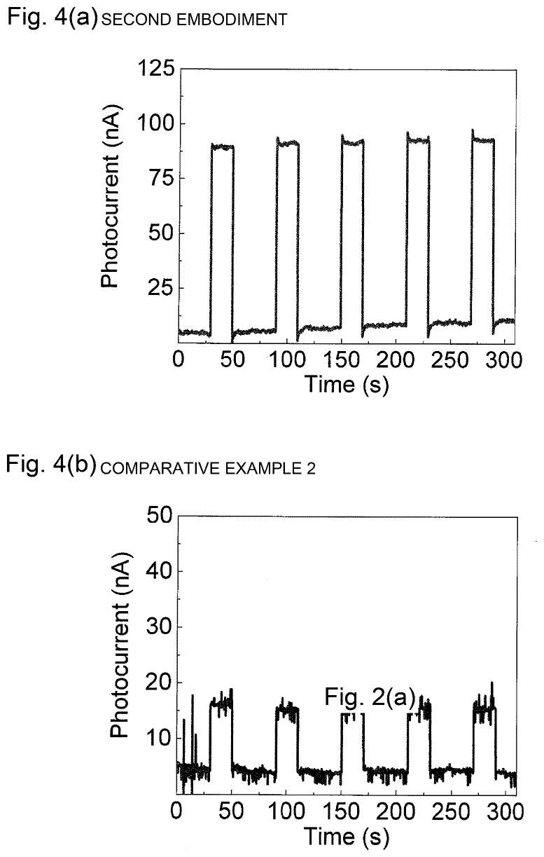

Regarding the semiconductor materials of First Embodiment and Comparative Example 1 produced above, the photoresponsivity to near-infrared rays was measured. As for the measuring method, comb-shaped electrodes were formed on the surface of the semiconductor material; and then the resultant was irradiated with near-infrared rays, and a photocurrent was measured at room temperature using a multimeter. The comb-shaped electrodes were formed by sequentially patterning a Ti film (film thickness: 5 nm) and a Au film (film thickness: 40 nm) in a comb shape on the surface of the PtSe₂ thin film modified with the Pt nanoparticles. The wavelength of the near-infrared rays used for the irradiation was 940 nm. The irradiation with the near-infrared rays was continuously performed for 20 seconds at 40-second intervals. In a four-point probe method, 0.5 V was loaded as a bias voltage. These measurement results are shown in FIG. 2.

From the measurement results of these response characteristics, it was found that the semiconductor material including the PtSe₂ thin film modified with the Pt nanoparticles (First Embodiment) was capable of generating photocurrents approximately five times larger than those by the semiconductor material including a conventional PtSe₂ thin film (Comparative Example 1). From this fact, it was confirmed that, when a PtSe₂ thin film is modified with Pt nanoparticles, optical semiconductor materials become excellent in terms of light-receiving sensitivity.

### [Evaluation of Carrier Lifetime by Open-Circuit Voltage Decay Method]

On the PtSe₂ thin film modified with the Pt nanoparticles, the carrier lifetime was measured using the open-circuit voltage decay method (OCVD method). The electrodes patterned in the comb shape on the PtSe₂ thin film modified with the Pt nanoparticles were connected to a probe station system. Irradiation with 940 nm infrared rays was performed as in the evaluation of the photoresponsivity to develop the effect of converting light to electricity. The relationship between the voltage drop at the time of stopping the irradiation with the infrared rays and the time was determined with the probe system, and a carrier lifetime t was calculated using the following formula.

$$τ = \frac{{k}_{b} T}{e} {( \frac{dV}{dt} )}^{- 1} \qquad [ Math 1 ]$$

FIG. 3 is a view showing the measurement results of the carrier lifetime characteristics. These test results show that the electron lifetime of the semiconductor material including the PtSe₂ thin film modified with the Pt nanoparticles of First Embodiment was 38.1 picoseconds. On the other hand, the electron lifetime of the semiconductor material including the conventional PtSe₂ thin film not modified with metal nanoparticles was 1.96 picoseconds. From these results, it is deemed that, as a result of suppression of carrier trapping by modification with the Pt nanoparticles, the lifetime of electrons becomes long. From this evaluation result regarding the electron lifetime, it was also confirmed that, when a PtSe₂ thin film is modified with Pt nanoparticles, optical semiconductor materials having an excellent light-receiving sensitivity can be produced.

### Second Embodiment

In the present embodiment, a thin film of PdSe₂ as a transition metal dichalcogenide thin film was formed on a base material, and the surface of the thin film was modified with Pt particles as metal nanoparticles, thereby producing a semiconductor material. Regarding each semiconductor material, the surface morphology was studied and semiconductor characteristics were evaluated in the same manner as in First Embodiment.

### [Manufacturing of Semiconductor Material]

### Formation of Transition Metal Dichalcogenide Thin Film

In the present embodiment, first, a Pd thin film was formed on a base material and then selenized, thereby manufacturing a transition metal dichalcogenide thin film (PdSe₂ thin film). A SiO₂ glass substrate (dimensions: 20×20, thickness: 1.5 mm) was provided as a base material, and a Pd thin film was formed on this base material by a vacuum deposition method (thermal deposition method). The substrate was set on the upper side in a vacuum chamber, and in the facing lower site in the chamber, a Pd deposition source was placed on a tungsten boat, followed by reducing the pressure in the chamber to 10-6 Pa order or less. After that, a current was caused to flow in the tungsten boat, and the Pd deposition source was heated by resistance heating to be vaporized, thereby forming a film of Pd on the facing substrate. At this time, deposition was performed until the film thickness of the Pd thin film reached 1 nm as measured using a film thickness meter.

Next, for selenization, the Pd-deposited substrate was set in a tubular furnace, and 5 g of a selenium powder was placed upstream of the substrate. At this time, the substrate temperature and the temperature of the selenium powder were each controllable. The inside of a reactor was purged with an argon gas (60 sccm) before film formation. The conditions for film formation were as described below. The film thickness of the PdSe₂ thin film formed on the base material in this sequence of the steps was 4 nm. This PdSe₂ thin film is a semiconductor material showing an n-type semiconductor tendency.
Flow rate of argon gas: 60 sccm
Temperature of substrate/heating temperature of selenium powder: 400° C./220° C.
Selenization time: 90 minutes
   Modification Step with Metal Nanoparticles

Next, the surface of the PdSe₂ thin film formed above was modified with Pt nanoparticles by an atomic layer deposition method. The device used was the same as the CVD device used to form the PtSe₂ thin film and also to modify the thin film with the Pt particles in First Embodiment. In addition, as a Pt complex that served as a precursor (raw material gas) of Pt nanoparticles, the same DDAP as above was used. The substrate on which the PtSe₂ thin film had been formed was placed in a reactor, and the reactor was purged with argon (80 sccm). Then the following (1) to (4) was regarded as one cycle. Furthermore, the substrate
(1) Introduction of raw material gas
   Heating temperature of raw material: 67° C.
   Carrier gas: Argon/10 sccm
   Introduction time: Four seconds
(2) Exhaustion of raw material gas
   Purged with argon gas (80 sccm)
   Introduction time: Five seconds
(3) Introduction of reaction gas.
   Reaction gas: Pure hydrogen/150 sccm
   Introduction time: Seven seconds
(4) Exhaustion of reaction gas
   Purged with argon gas (80 sccm)
   Introduction time: Five seconds

In the present embodiment, 10 cycles each consisting of (1) to (4) above were performed to thereby modify the surface of the PdSe₂ thin film with the Pt nanoparticles to manufacture a semiconductor material.

### Comparative Example 2: As Comparative Example 2 with respect to Second

Embodiment described above, a semiconductor material was manufactured in which modification of surface defects in a PdSe₂ thin film was not performed. The semiconductor material was produced by forming the PdSe₂ thin film on a substrate and then not performing modification with Pt nanoparticles in Second Embodiment.

### [Measurement of Average Particle Diameter and Percentage of Area of Metal Nanoparticles]

For the Pt nanoparticles on the surface of the semiconductor material of Second Embodiment, the average particle diameter and the percentage of the area were measured. The method for measuring the average particle diameter and the measurement of the percentage of the area of the Pt nanoparticles were the same as in First Embodiment. As a result, the average particle diameter of the Pt nanoparticles was 7.98 nm. The percentage of the area of the Pt nanoparticles was 10.16%.

### [Evaluation of Photoresponsivity of Semiconductor Material]

On the semiconductor materials of Second Embodiment and Comparative Example 2 produced above, the photoresponsivity to near-infrared rays was measured. As for the measurement method and the method for electrode formation were the same as in First Embodiment and Comparative Example 1 (near-infrared ray wavelength: 940 nm). These measurement results are shown in FIG. 4.

From the measurement result of FIG. 4, it is found that the semiconductor material including the PdSe₂ thin film modified with the Pt nanoparticles (Second Embodiment) was capable of generating photocurrents approximately five times larger than those by the semiconductor material including a conventional PdSe₂ thin film (Comparative Example 2). From this fact, it was confirmed that, when a PdSe₂ thin film is modified with Pt nanoparticles, optical semiconductor materials become excellent in terms of light-receiving sensitivity.

### [Carrier Lifetime Evaluation by Open-Circuit Voltage Decay Method]

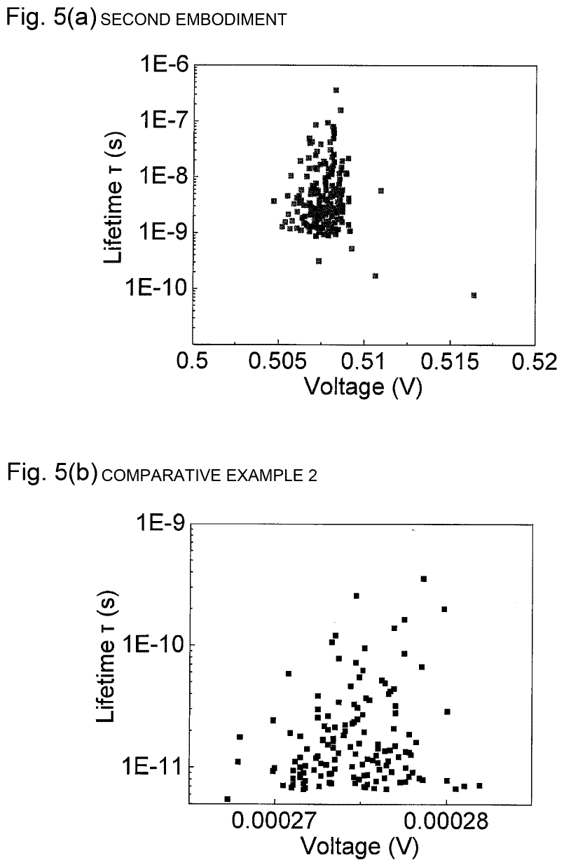

On the PdSe₂ thin film modified with the Pt nanoparticles, the carrier lifetime was measured using the OCVD method in the same manner as in First Embodiment. The results are shown in FIG. 5. FIG. 5 shows that the electron lifetime of the semiconductor material including the PdSe₂ thin film modified with the Pt nanoparticles of Second Embodiment was 77.9 picoseconds. In contrast, the electron lifetime of the semiconductor material including the PdSe₂ thin film with no metal nanoparticles of Comparative Example 2 was 7.18 picoseconds. In the present embodiment as well, an increase in the electron lifetime by the modification with the Pt nanoparticles was confirmed.

Third Embodiment: In the present embodiment, a thin film of PtSe₂ as a transition metal dichalcogenide thin film was formed on a base material, and the surface of the thin film was modified with Ru particles as metal nanoparticles, thereby producing a semiconductor material. Regarding the semiconductor material, the photoresponsivity to near-infrared rays was evaluated and the surface morphology was studied.

### [Manufacturing of Semiconductor Material]

Formation of Transition Metal Dichalcogenide Thin Film

A SiO₂ glass substrate was used as a base material as in First Embodiment, and a PtSe₂ thin film was formed by a CVD method in the same manner as in First Embodiment. A platinum complex (DDAP) was used as a thin film raw material. The platinum complex was heated to be vaporized, and introduced together with a carrier gas into the reactor. The platinum complex vaporized was decomposed on the substrate, and platinum and selenium were reacted with each other to precipitate PtSe₂, thereby forming a thin film. The conditions for film formation were the same as those in First Embodiment, and the film thickness of the PtSe₂ thin film was 4 nm.

Modification Step with Metal Nanoparticles

The surface of the PtSe₂ thin film formed above was modified with Ru nanoparticles by an atomic layer deposition method. The device used was the same as the CVD device used to form the PtSe₂ thin film was used. As a Ru complex as a precursor (raw material gas) of the Ru nanoparticles, tricarbonyl(trimethylenemethane) ruthenium (Ru(TMM)(CO)₃) was used. The substrate on which the PtSe₂ thin film had been formed was placed in a reactor, and the reactor was purged with argon (100 sccm). Then, the following (1) to (4) was regarded as one cycle.
(1) Introduction of raw material gas
   Heating temperature of raw material: 10° C.
   Carrier gas: Argon/50 sccm
   Introduction time: 10 seconds
(2) Exhaustion of raw material gas
   Purged with argon gas (100 sccm)
   Introduction time: 10 seconds
(3) Introduction of reaction gas
   Reaction gas: Pure oxygen/50 sccm
   Introduction time: 10 seconds
(4) Exhaustion of reaction gas
   Purged with argon gas (100 sccm)
   Introduction time: 10 seconds

In the present embodiment, 50 cycles each consisting of (1) to (4) above were performed to thereby modify the surface of the PtSe₂ thin film with the Ru nanoparticles to manufacture a semiconductor material.

### [Measurement of Average Particle Diameter and Percentage of Area of Metal Nanoparticles]

For the Ru nanoparticles on the surface of the semiconductor material of Third Embodiment, the average particle diameter and the percentage of the area were measured. The measurement of the average particle diameter and the percentage of the area of the Ru nanoparticles was based on surface observation with SEM in the same manner as in First Embodiment. The average particle diameter of the Ru nanoparticles was 12.47 nm. The percentage of the area of the Ru nanoparticles of the present embodiment was 1.98%. FIG. 6 shows an example of a SEM image of the semiconductor material (Ru/PtSe₂) manufactured in Third Embodiment. [Evaluation of Photoresponsivity of Semiconductor Material]

On the semiconductor material of Third Embodiment produced above, the photoresponsivity to near-infrared rays was measured. As for the measurement method and the method for electrode formation were the same as in First Embodiment, and the wavelengths of the near-infrared rays used for irradiation were 740 nm, 850 nm and 940 nm. These measurement results are shown in FIG. 7. FIG. 7 shows the results of the semiconductor material (Ru/PtSe₂) of the present embodiment and the semiconductor material without modification with Ru particles (bare PtSe₂ thin film: Comparative Example 1).

From the measurement results of FIG. 7, it is found that the semiconductor material including the PtSe₂ thin film modified with the Ru nanoparticles (Third Embodiment) was capable of generating a higher photocurrent than the semiconductor material including only the PtSe₂ thin film (Comparative Example 1) in all wavelength ranges. In the present embodiment, it was possible to generate photocurrents approximately eight times larger. From the above-described results, it was confirmed that the light-receiving sensitivity of the transition metal dichalcogenide thin film was also improved by modification with the Ru nanoparticles.

### INDUSTRIAL APPLICABILITY

As described above, the semiconductor material of the invention and the method for producing the same satisfy all requirements, specifically, a high light-receiving sensitivity, a low production cost and use at room temperature, and the semiconductor material is useful as light-receiving elements. Particularly, since the light-receiving sensitivity in the near-infrared range is extremely superior to those of conventional transition metal dichalcogenides, the semiconductor material of the present invention can be expected to contribute to additional improvement in measurement accuracy as a material for light-receiving elements in LIDAR applications.

What is claimed is:

1. A semiconductor material comprising:
a base material; and
a thin film formed on the base material and comprising a transition metal dichalcogenide represented by MX₂, wherein M is a transition metal and X is a chalcogen atom except oxygen,
wherein the semiconductor material comprises metal nanoparticles comprising metallic N and modifying a surface of the thin film.

2. The semiconductor material according to claim 1, wherein an average particle diameter of the metal nanoparticles is 2 nm or more and 50 nm or less.

3. The semiconductor material according to claim 1, wherein a work function of the metallic N of the metal nanoparticles is larger than a band gap of the transition metal dichalcogenide MX₂ of the thin film.

4. The semiconductor material according to any one of claims 1 to 3, wherein the transition metal M of the transition metal dichalcogenide MX₂ is Pt or Pd.

5. The semiconductor material according to any one of claims 1 to 4, wherein the chalcogen X of the transition metal dichalcogenide MX₂ is sulfur, selenium, or tellurium.

6. The semiconductor material according to any one of claims 1 to 5, wherein the metallic N of the metal nanoparticles is a precious metal.

7. The semiconductor material according to any one of claims 1 to 6, wherein, when the surface of the thin film comprising the transition metal dichalcogenide and modified with the metal nanoparticles is observed, a percentage of the area of the metal nanoparticles is 5% or more and 20% or less of an observation field region.

8. The semiconductor material according to any one of claims 1 to 7, wherein the base material comprises glass, quartz, silicon, carbon, ceramic, or metal.

9. A light-receiving element comprising the semiconductor material defined in any one of claims 1 to 8.

10. A method for producing the semiconductor material defined in any one of claims 1 to 8, the method comprising:
forming the thin film comprising the transition metal dichalcogenide MX₂ on the base material; and
modifying the surface of the thin film with the metal nanoparticles comprising the metallic N,
wherein an atomic layer deposition method is used for modifying with the metal nanoparticles.

11. The method for producing the semiconductor material according to claim 10, wherein a physical deposition method or a chemical deposition method is used for forming the thin film comprising the transition metal dichalcogenide MX₂.
